(19) United States
(12) Patent Application Publication
(10) Pub. No.: US 2024/0321588 A1
(43) Pub. Date: Sep. 26, 2024

(54) METHOD FOR PROCESSING THREE-DIMENSIONAL (3D) SILICON-BASED TRANSFER STRUCTURE BASED ON PHOTOSENSITIVE COMPOSITE, AND DEVICE MANUFACTURED THEREBY

(71) Applicant: SHANGHAI JIAO TONG UNIVERSITY, Shanghai (CN)

(72) Inventors: Ziqi ZHANG, Shanghai (CN); Liang ZHOU, Shanghai (CN); Chengrui ZHANG, Shanghai (CN); Junfa MAO, Shanghai (CN)

(73) Assignee: SHANGHAI JIAO TONG UNIVERSITY, Shanghai (CN)

(21) Appl. No.: 18/271,283

(22) PCT Filed: Dec. 19, 2022
(86) PCT No.: PCT/CN2022/139915

§ 371 Date: May 14, 2024

(30) Foreign Application Priority Data
Mar. 14, 2022 (CN) 202210249629.4

(51) Int. Cl. H01L 21/311; H01L 21/027; H01L 21/033; H01L 21/768

(52) U.S. Cl. CPC H01L 21/31144; H01L 21/0274; H01L 21/0337; H01L 21/76898

(57) ABSTRACT

A method for processing a three-dimensional (3D) silicon-based transfer structure based on a photosensitive composite, and a device manufactured thereby, include: S1: manufacturing a front protective film and a back protective film on a silicon-based substrate; S2: manufacturing a waveguide metal sidewall on a back of the silicon-based substrate, and forming a through-silicon via (TSV); S3: manufacturing a back-cavity structure of the transfer structure on a front of the silicon-based substrate, and filling the back-cavity structure with the photosensitive composite; S4: manufacturing a medium mask layer on the back-cavity structure, and manufacturing a top metal pattern on a top medium layer; and S5: conducting bulk silicon etching and scribing through photolithographic masking and dry etching to obtain a complete transfer structure.

### TECHNICAL FIELD

The present disclosure relates to the technical field of wafer-level three-dimensional (3D) heterogeneous integration packaging processes, and in particular relates to a method for processing a 3D silicon-based transfer structure based on a photosensitive composite, and a device manufactured thereby.

### BACKGROUND

In a wafer-level 3D heterogeneous integration packaging process, a chip is integrated with various passive components into a system directly on a silicon-based wafer, and a surface of the chip is subjected to rewiring to allow a fan-out effect. In the wafer-level 3D heterogeneous integration packaging process, a micro-nano process device can be directly used to integrate hundreds or more of chips in a large-batch system at one time and connect these chips with passive components such as filters, antennas, and balanced-to-unbalanced transformers (Balun), which greatly improves the packaging efficiency, reduces the cost, and improves the overall performance of the system. Therefore, the wafer-level 3D heterogeneous integration packaging process is an important way to allow system-in-package (SiP).

Through-silicon via (TSV) electroplating is a core technique for 3D heterogeneous integration. During TSV electroplating, blind vias on a silicon-based surface are subjected to electroplating to allow metal growth, and this vertical interconnection solution can reduce an interconnection distance of a system, reduce a transmission delay, and improve a capacitance-inductance effect, thereby allowing the miniaturization and high-density integration of components.

With the rapid development of the information age, radar communication systems are constantly iteratively updated in the direction of miniaturization, high performance, and high integration level, and the traditional Moore's Law can no longer be applied to the current high-density iterative process in a two-dimensional (2D) plane. Therefore, the 3D heterogeneous integration technique has been widely developed. Currently, the improvement of an interconnection solution is a principle problem faced by the development of miniaturized and high-performance radar communication systems in the millimeter wave frequency range. A traditional interconnection solution is mainly based on plane transitions, and allows fan-out with microstrips from a chip, such that systems manufactured on substrates of a same thickness each have a large size and a fan-out interface that is not easily integrated with interfaces such as waveguides. The reduction of an overall size of a system and the change of a planar transfer structure into a 3D structure to allow a 3D integration effect has become a major research hotspot. In addition, when a metal waveguide is integrated in a silicon-based substrate to interconnect chips, the processing of a transfer structure for fan-out of a microstrip from a chip to a rectangular waveguide is a very challenging and difficult task.

### SUMMARY

In view of the defects in the prior art, the present disclosure provides a method for processing a 3D silicon-based transfer structure based on a photosensitive composite, and a device manufactured thereby.

For the method for processing a 3D silicon-based transfer structure based on a photosensitive composite and the device manufactured thereby provided according to the embodiments of the present disclosure, the present disclosure adopts the following solutions:

In a first aspect, the present disclosure provides a method for processing a 3D silicon-based transfer structure based on a photosensitive composite, including:
S1: manufacturing a front protective film and a back protective film on a silicon-based substrate;
S2: manufacturing a waveguide metal sidewall on a back of the silicon-based substrate, and forming a TSV;
S3: manufacturing a back-cavity structure of the transfer structure on a front of the silicon-based substrate, and filling the back-cavity structure with the photosensitive composite;
S4: manufacturing a medium mask layer on the back-cavity structure, and manufacturing a top metal pattern on a top medium layer; and
S5: conducting bulk silicon etching and scribing through photolithographic masking and dry etching to obtain a complete transfer structure.

Further, S2 includes:
S2.1: spin-coating a photoresist on the back protective film, and developing to obtain a mask;
S2.2: etching the back protective film with the lithographic mask;
S2.3: conducting bulk silicon etching through dry etching, and removing the photoresist;
S2.4: sputtering a metal seed layer on the back of the silicon-based substrate;
S2.5: electroplating and solidifying a deep via formed after the bulk silicon etching; and
S2.6: after the electroplating is completed, mechanically smoothing a metal copper protruding on the back of the silicon-based substrate.

Further, in S2.3, the bulk silicon etching is conducted with a size of 421 μm;
in S2.4, during the sputtering, a chromium metallic layer is first sputtered;
in S2.5, a surface metal atom activity inhibitor is added to an electroplating solution; and
in S2.6, the mechanical smoothing is conducted with a 600-BLD04 grinding wheel.

Further, S3 includes:
S3.1: spin-coating a photoresist on the front protective film, and manufacturing a back-cavity pattern;
S3.2: dry etching the front protective film and the silicon-based substract to form the back-cavity structure, and cleaning to remove the photoresist;
S3.3: sputtering a bottom seed layer on the front of the silicon-based substrate;
S3.4: spin-coating a photoresist on the bottom seed layer;
S3.5: electroplating the bottom seed layer, and cleaning to remove the photoresist;
S3.6: etching off the bottom seed layer with an ion beam to form a complete bottom structure;
S3.7: filling a back cavity with benzocyclobutene (BCB) through multiple times of spin-coating, such that the back cavity is fully filled after curing; and
S3.8: mechanically smoothing a top BCB medium layer.

Further, in S3.2, the dry etching to form the back-cavity structure is conducted with a size of 79 μm; and
in S3.5, a thermally-conductive adhesive tape is used to bond a metal exposed on the back during the electroplating of the front of the silicon-based substrate.

Further, S4 includes:
S4.1: spin-coating a medium layer as a back-cavity mask layer on the BCB medium layer that has been mechanically smoothed on the front of the silicon-based substrate;
S4.2: thoroughly etching off the BCB outside the back-cavity mask layer through medium etching;
S4.3: spin-coating a surface medium layer on the back-cavity mask layer on the front of the silicon-based substrate, and manufacturing a pattern;
S4.4: sputtering a top metal layer on the surface medium layer on the front of the silicon-based substrate;
S4.5: spin-coating a photoresist on the top metal layer, and manufacturing a pattern;
S4.6: electroplating the top metal layer, and removing the residual photoresist; and
S4.7: using an ion beam to etch off a part of the top metal layer that is not electroplated.

Further, in S4.1, a size of the medium mask layer is expanded by 200 μm compared with a perimeter of the back-cavity structure; and
in S4.2, a top medium mask layer left after the medium etching has a height of 8 μm.

Further, S5 includes:
S5.1: spin-coating a photoresist on the back of the silicon-based substrate, and developing to obtain a mask;
S5.2: conducting the bulk silicon etching through the dry etching, and removing the residual photoresist; and
S5.3: scribing the silicon-based substrate to complete manufacture of the transfer structure.

Further, the front protective film and the back protective film each are a Si₃N₄ film; and
the dry etching refers to inductively coupled plasma (ICP) dry etching.

In a second aspect, the present disclosure provides a device manufactured by the method for processing a 3D silicon-based transfer structure based on a photosensitive composite described above.

### BRIEF DESCRIPTION OF THE DRAWINGS

Other features, objectives, and advantages of the present disclosure will become more apparent by reading the detailed description of non-limiting embodiments with reference to the following accompanying drawings.

FIG. 1 is a cross-sectional view of a 3D transfer structure; and

FIG. 2 is a basic flow chart of the method of the present disclosure.

Reference numerals:

| | |
|---|---|
| 101: 4-inch high-impedance | 102: Si₃N₄ film |
| circular silicon wafer | |
| 103: rectangular waveguide metal | 104: substrate integrated waveguide |
| sidewall | (SIW) back-cavity structure |
| 105: Metal bottom layer | 106: Coupling window |
| 107: Top medium layer | 108: Top metal layer |
| 109: Air chamber | |

### DETAILED DESCRIPTION OF THE EMBODIMENTS

The present disclosure is described in detail below with reference to specific embodiments. The following embodiments will help those skilled in the art further understand the present disclosure, but will not limit the present disclosure in any way. It should be noted that several variations and improvements can also be made by a person of ordinary skill in the art without departing from the conception of the present disclosure. These all fall within the protection scope of the present disclosure.

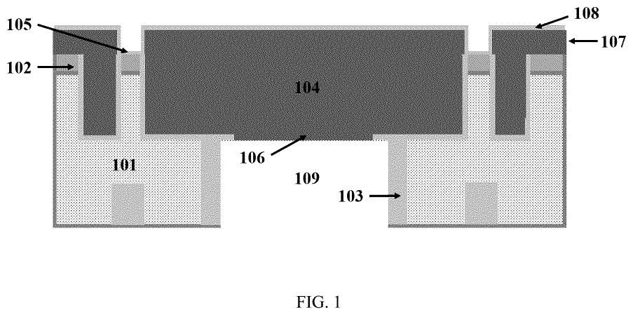

In view of the problem that the photosensitive composite BCB cannot allow a large thickness when serving as a medium, the problem that a different coefficient of thermal expansion (CTE) of BCB from other materials leads to edge cracking during processing and thus leads to fracture of a trace of a metal in a top medium layer at a cracking site, and the solution problems occurring when a traditional planar interconnection structure is improved and a metal rectangular waveguide is integrated in a silicon-based substrate to allow a 3D integrated architecture, the embodiment of the present disclosure provides a method for processing a 3D silicon-based transfer structure based on a photosensitive composite. As shown in FIG. 1, the method specifically includes:
S1: A front protective film and a back protective film (namely, double-sided protective films) are manufactured on a silicon-based substrate.
S2: A waveguide metal sidewall is manufactured on a back of the silicon-based substrate through dry etching, and a TSV is formed.
S2 specifically includes the following steps:
S2.1: A photoresist is spin-coated on the back protective film, and development is conducted to obtain a mask.
S2.2: The back protective film is etched with the lithographic mask.
S2.3: Bulk silicon etching is conducted through dry etching, and the photoresist is removed, where the bulk silicon etching is conducted with a size of 421 μm.
S2.4: A metal seed layer is sputtered on the back of the silicon-based substrate. During the sputtering, a chromium metallic layer is first sputtered, which helps to increase the adhesion of the metal copper.
S2.5: The TSV is electroplated, that is, a deep via formed after the bulk silicon etching is electroplated, and sufficient metal growth is allowed. In this step, a surface metal atom activity inhibitor is added to an electroplating solution, which can ensure the anisotropism of electroplating inside and outside the via.
S2.6: After the electroplating is completed, a metal copper protruding on the back of the silicon-based substrate is mechanically smoothed. In this step, the mechanical smoothing is conducted with a 600-BLD04 grinding wheel.
S3: A back-cavity structure of the transfer structure is manufactured on a front of the silicon-based substrate, and the back-cavity structure is filled with the photosensitive composite.
S3 specifically includes:
S3.1: A photoresist is spin-coated on the front protective film, and a back-cavity pattern is manufactured.
S3.2: The front protective film and the silicon-based structure are dry etched to form the back-cavity structure, and then cleaned to remove the photoresist. In this step, the dry etching to form the back-cavity structure is conducted with a size of 79 μm.
S3.3: A bottom seed layer is sputtered on the front of the silicon-based substrate.
S3.4: A photoresist is spin-coated on the bottom seed layer.
S3.5: The bottom seed layer is electroplated and then cleaned to remove the photoresist. In this step, a thermally-conductive adhesive tape is used to bond a metal exposed on the back during the electroplating of the front of the silicon-based substrate.
S3.6: The bottom seed layer is etched off with an ion beam to form a complete bottom structure.
S3.7: A back cavity is filled with BCB through multiple times of spin-coating, such that the back cavity is fully filled after the BCB is cured.
S3.8: Atop BCB medium layer is mechanically smoothed.
S4: A medium mask layer is manufactured on the back-cavity structure, and a top metal pattern is manufactured on a top medium layer.
S4 specifically includes: S4.1: A medium layer is spin-coated as a back-cavity mask layer on the BCB medium layer that has been mechanically smoothed on the front of the silicon-based substrate. In this step, a size of the medium mask layer is expanded by 200 μm compared with a perimeter of the back-cavity structure.
S4.2: The BCB outside the back-cavity mask layer is thoroughly etched off through medium etching. In this step, a top medium mask layer left after the medium etching has a height of 8 μm.
S4.3: A surface medium layer is spin-coated on the back-cavity mask layer on the front of the silicon-based substrate, and a pattern is manufactured.
S4.4: A top metal layer is sputtered on the surface medium layer on the front of the silicon-based substrate.
S4.5: A photoresist is spin-coated on the top metal layer, and a pattern is manufactured.
S4.6: The top metal layer is electroplated, and the residual photoresist is removed.
S4.7: An ion beam is used to etch off a part of the top metal layer that is not electroplated.
S5: Bulk silicon etching and scribing are conducted through photolithographic masking and dry etching to obtain a complete transfer structure.
S5 specifically includes:
S5.1: A photoresist is spin-coated on the back of the silicon-based substrate, and development is conducted to obtain a mask.
S5.2: The bulk silicon etching is conducted through the dry etching, and the residual photoresist is removed.
S5.3: The silicon-based substrate is scribed to complete manufacture of the transfer structure.

The front protective film and the back protective film (namely, double-sided protective films) in the embodiment of the present disclosure each are a Si₃N₄ film 102, and the dry etching involved in all process flows refers to ICP dry etching. Specifically, the dry etching refers to ICP etching, where the silicon-based substrate is anisotropically etched with the help of plasma generated after glow discharge in a gas. During the etching, etching processes and protection processes are conducted alternately, that is, the silicon-based substrate is etched with fluorine-based reactive oxygen species (ROS), and then a sidewall is passivated with a fluorine-based gas. After isotropic etching, because a passivation film is formed by gas bombardment on a longitudinal sidewall of the silicon-based substrate, the passivation layer on the sidewall will not be etched off during the next etching cycle, and only a bottom of an etched trench is etched by a fluorine-based ROS gas. The repeated etching and passivation in this way can improve an anisotropic effect of dry etching, allows a final structure to have an inclination angle of nearly 90°, and can lead to a structure with a high aspect ratio, which ensures a subsequent fabrication of a structure such as TSV through dry etching.

The embodiment of the present disclosure also provides a device manufactured by the method for processing a 3D silicon-based transfer structure based on a photosensitive composite described above.

The present disclosure is specifically described below.

The embodiment of the present disclosure provides a method for processing a 3D silicon-based transfer structure based on a photosensitive composite, where a TSV is first etched on a back of a silicon-based substrate, a seed layer is sputtered on the back, then the TSV is electroplated, and after a metal solidly grows in a via, mechanical smoothing is conducted; then a rectangular via with a column is dry etched on a front of the silicon-based wafer, a metal layer is sputtered, and photolithographic patterning and electroplating are conducted to obtain a target pattern; BCB is filled in the via through multiple times of spin-coating and curing, and a BCB mask layer is manufactured on a top layer of the silicon-based wafer to cover an edge of the via; and then a top medium layer 107 and a metal layer are patterned, and a rectangular waveguide on the back is etched. The determination and implementation of this solution overcomes the difficulties in integration of a rectangular metal waveguide into a silicon-based wafer, allows the conversion from a grounded coplanar waveguide to a metal waveguide, and provides an efficient and reliable transfer solution for 3D heterogeneous integration. In a process flow, the process parameters and masking solution of spin-coating of a medium are improved to allow a large-thickness medium layer without cracking.

Specific process steps are as follows:
(1) A protective film is manufactured on each of a front and a back of a silicon wafer.
(2) A photoresist is spin-coated on the back of the silicon wafer, then baked and performed lithographic development, and then the protective film and the silicon wafer are etched.
(3) The photoresist is removed, a metal seed layer is sputtered, then TSV electroplating is conducted, and mechanical smoothing is conducted.
(4) A photoresist is spin-coated on the front of the silicon wafer, then baked, and subjected to lithographic development, and then the protective film and the silicon wafer are etched to a specified depth.
(5) The photoresist is removed, a metal seed layer is sputtered, a surface is patterned with a photoresist, and then metal electroplating is conducted.
(6) The photoresist and the seed layer are removed to form a complete bottom structure.
(7) The photosensitive medium BCB is filled multiple times and fully cured, and then a top layer is smoothed.
(8) A photosensitive medium BCB layer is spin-coated as a back-cavity mask layer, and the overall structure is subjected to medium etching.
(9) A top photosensitive medium BCB layer is spin-coated, and a metal seed layer is sputtered.
(10) Atop metal layer is patterned, and the metal seed layer is removed.
(11) A photoresist is spin-coated on the back of the silicon wafer, and the etching of the metal blind via of the silicon wafer is completed to form a metal rectangular waveguide.
(12) The silicon-based wafer is scribed to obtain a complete transfer structure unit.

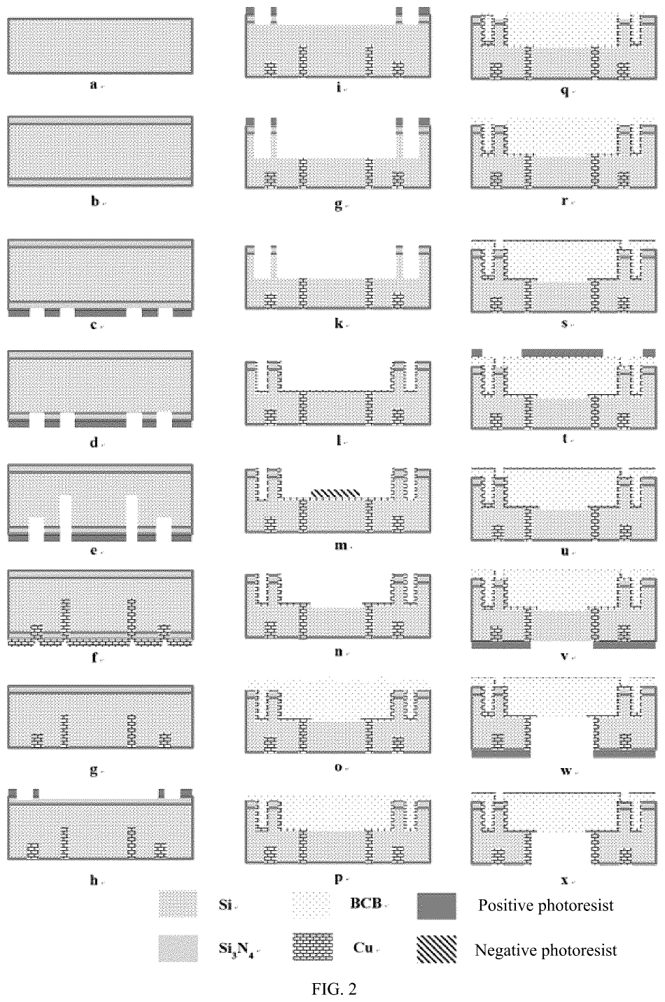

As shown in FIG. 1 and FIG. 2, the method of the present disclosure is implemented as follows:
(a) 4-inch high-impedance circular silicon wafer 101 with a thickness of 500 μm in which both sides are polished is taken as a silicon-based substrate, and cleaned for later use, as shown in (a) of FIG. 2.
(b) Si₃N₄ film 102 is deposited on each of two sides of the high-impedance circular silicon wafer through low pressure chemical vapor deposition (LPCVD), as shown in (b) of FIG. 2.
(c) A photoresist is spin-coated on a back of the silicon wafer, and a rectangular waveguide sidewall pattern is developed, as shown in (c) of FIG. 2.
(d) With the photoresist as a mask, the protective film Si₃N₄ is subjected to medium etching to expose a silicon-based surface below the protective film, as shown in (d) of FIG. 2.
(e) Further with the photoresist as a mask, the exposed silicon-based surface is subjected to deep silicon etching through dry etching to form a blind via, as shown in (e) of FIG. 2.
(f) The photoresist is removed with acetone, a Cr/Cu seed layer is sputtered, and TSV electroplating is directly conducted to form a rectangular waveguide metal sidewall 103, as shown in (f) of FIG. 2.
(g) A DISCO-BG810 thinning machine and a 600-BLD04 grinding wheel are used to mechanically smooth and polish a metal on the back of the silicon wafer, as shown in (g) of FIG. 2.
(h) A photoresist is spin-coated on a front of the silicon wafer, and an SIW back-cavity pattern is developed, as shown in (h) of FIG. 2.
(i) With the photoresist as a mask, the protective film Si₃N₄ is subjected to medium etching to expose a silicon-based surface below the protective film, as shown in (i) of FIG. 2.
(j) Further with the photoresist as a mask, the exposed silicon-based surface is subjected to deep silicon etching through dry etching to form SIW back-cavity structure 104, as shown in (j) of FIG. 2.
(k) The photoresist is washed off with acetone, and cleaning is conducted once again under ultrasonic waves to thoroughly remove the residual photoresist, as shown in (k) of FIG. 2.
(l) A Cr/Cu seed layer is sputtered on the front of the silicon wafer, as shown in (l) of FIG. 2.
(m) A photoresist is spin-coated on the front of the silicon wafer, and a metal bottom layer pattern is subjected to lithographic development in the SIW back cavity, as shown in (m) of FIG. 2.
(n) With the photoresist in the via as a mask, metal bottom layer 105 is electroplated, the photoresist is washed off with acetone, and the metal seed layer covered by the photoresist is thoroughly etched off with an ion beam to expose coupling window 106, as shown in (n) of FIG. 2.
(o) BCB is spin-coated multiple times, and then subjected to exposure, development, and curing, such that the SIW back-cavity structure 104 is fully filled, as shown in (o) of FIG. 2.
(p) A DISCO-BG810 thinning machine is used to polish an uneven BCB layer on the front of the silicon wafer to ensure that the top BCB layer is in a same plane, as shown in (p) of FIG. 2.
(q) A BCB layer is spin-coated as a mask for filling of a medium of the back cavity on the front of the silicon wafer, and the front overall structure is subjected to medium etching to ensure that a final mask part is higher than the silicon-based surface, as shown in (q) of FIG. 2.
(r) A BCB layer is spin-coated as top medium layer 107, subjected to pre-baking, exposure, development, and hard curing, and etched to a corresponding thickness, as shown in (r) of FIG. 2.
(s) A Cr/Cu seed layer is sputtered on the top medium layer 107, as shown in (s) of FIG. 2.
(t) A photoresist is spin-coated on the seed layer, and then subjected to lithographic development to obtain a top metal pattern, as shown in (t) of FIG. 2.
(u) With the photoresist on the seed layer as a mask, a top metal layer 108 is electroplated, the photoresist is washed off with acetone, and the metal seed layer covered by the photoresist is thoroughly etched off with an ion beam, as shown in (u) of FIG. 2.
(v) A photoresist is spin-coated on the back of the silicon wafer, and a pattern in a rectangular waveguide cavity is developed, as shown in (v) of FIG. 2.
(w) With the photoresist as a mask, the exposed silicon is dry etched, that is, silicon in the metal rectangular waveguide cavity is completely etched off to form an air chamber 109, as shown in (w) of FIG. 2.
(x) The residual photoresist is washed off with acetone, and the silicon wafer is scribed with a DISCO-DAD3650 scribing machine to obtain a transfer structure unit, as shown in (x) of FIG. 2.

In the embodiment of the present disclosure, a mixed solution of an activity inhibitor, an accelerating agent, and a leveling agent is added to an electroplating solution to allow an electroplating effect from bottom to top during electroplating, such that a structure with sufficient metal growth in a via and an inhibited surface is finally obtained. The inhibitor with a strong adsorption capacity can inhibit the growth of a metal copper on a surface of the substrate; the accelerating agent can converge at a bottom of a via to increase metal electroplating speeds in blind vias with different aspect ratios; and the leveling agent can inhibit metal bumps generated on a surface of the substrate due to non-uniform currents.

The embodiment of the present disclosure provides a method for processing a 3D silicon-based transfer structure based on a photosensitive composite, and a device manufactured thereby. The present disclosure increases a thickness of the BCB medium through multiple times of spin-coating and curing, which solves the problem that the use of the photosensitive composite BCB as a medium can only lead to a limited thickness; and the present disclosure solves the problem that a different CTE of BCB from other materials leads to edge cracking, and thus prevents a trace of a metal in a top layer from fracturing. In addition, the present disclosure provides a solution for manufacturing a metal waveguide on a silicon-based substrate, where a metal waveguide is integrated in the silicon-based substrate through the combination of TSV manufacturing and dry etching, which reduces the interconnection loss and improves the diversity and reliability of the wafer-level heterogeneous integration packaging process. In view of problems in radio frequency (RF), fan-out, and interconnection of chips during a silicon-based system-level integration process, the traditional planar fan-out interconnection solution is replaced by the introduction of a metal rectangular waveguide on a silicon-based substrate to form a 3D interconnection structure in the present disclosure, which greatly reduces an overall size of an RF system, provides a waveguide output interface while allowing miniaturization, and improves the degree of freedom (DOF) of interconnection and the flexibility.

Those skilled in the art are aware that, in addition to being implemented with a pure computer-readable program code, the system and each apparatus, module, and unit thereof provided in the present disclosure can allow a same program in a form of a logic gate, a switch, an application-specific integrated circuit, a programmable logic controller, or an embedded microcontroller by performing logic programming on the method steps. Therefore, the system and each apparatus, module, and unit thereof provided in the present disclosure can be regarded as a kind of hardware component. The apparatus, module, and unit included therein for realizing each function can also be regarded as a structure in the hardware component; and the apparatus, module, and unit for realizing each function can also be regarded as a software module for implementing the method or a structure in the hardware component.

Compared with the prior art, the present disclosure has following beneficial effects:
1. The present disclosure increases a thickness of the BCB medium through multiple times of spin-coating and curing, which solves the problem that the use of the photosensitive composite BCB as a medium can only lead to a limited thickness.
2. The present disclosure also solves the problem that a different CTE of BCB from other materials leads to edge cracking, and thus prevents a trace of a metal in a top layer from fracturing. In addition, the present disclosure provides a solution for manufacturing a metal waveguide on a silicon-based substrate, where a metal waveguide is integrated in the silicon-based substrate through the combination of TSV manufacturing and dry etching, which reduces the interconnection loss and improves the diversity and reliability of the wafer-level heterogeneous integration packaging process.
3. In view of problems in RF, fan-out, and interconnection of chips during a silicon-based system-level integration process, the traditional planar fan-out interconnection solution is replaced by the introduction of a metal rectangular waveguide on a silicon-based substrate to form a 3D interconnection structure in the present disclosure, which greatly reduces an overall size of an RF system, and provides a waveguide output interface while allowing miniaturization.

The specific embodiments of the present disclosure are described above. It should be understood that the present disclosure is not limited to the above specific implementations, and a person skilled in the art can make various variations or modifications within the scope of the claims without affecting the essence of the present disclosure. The embodiments of the present disclosure and features in the embodiments may be arbitrarily combined with each other in a non-conflicting situation.

1. A method for processing a three-dimensional (3D) silicon-based transfer structure based on a photosensitive composite, comprising:
S1: manufacturing a front protective film and a back protective film on a silicon-based substrate;
S2: manufacturing a waveguide metal sidewall on a back of the silicon-based substrate, and forming a through-silicon via (TSV);
S3: manufacturing a back-cavity structure of the transfer structure on a front of the silicon-based substrate, and filling the back-cavity structure with the photosensitive composite;
S4: manufacturing a medium mask layer on the back-cavity structure, and manufacturing a top metal pattern on a top medium layer; and
S5: conducting bulk silicon etching and scribing through photolithographic masking and dry etching to obtain a complete transfer structure.

2. The method for processing a 3D silicon-based transfer structure based on a photosensitive composite according to claim 1, wherein S2 comprises:
S2.1: spin-coating a photoresist on the back protective film, and developing to obtain a mask;
S2.2: etching the back protective film with the lithographic mask;
S2.3: conducting bulk silicon etching through dry etching, and removing the photoresist;
S2.4: sputtering a metal seed layer on the back of the silicon-based substrate;
S2.5: electroplating and solidifying a deep via formed after the bulk silicon etching; and
S2.6: after the electroplating is completed, mechanically smoothing a metal copper protruding on the back of the silicon-based substrate.

3. The method for processing a 3D silicon-based transfer structure based on a photosensitive composite according to claim 2, wherein in S2.3, the bulk silicon etching is conducted with a size of 421 μm;
in S2.4, during the sputtering, a chromium metallic layer is first sputtered;
in S2.5, a surface metal atom activity inhibitor is added to an electroplating solution; and
in S2.6, the mechanical smoothing is conducted with a 600-BLD04 grinding wheel.

4. The method for processing a 3D silicon-based transfer structure based on a photosensitive composite according to claim 1, wherein S3 comprises:
S3.1: spin-coating a photoresist on the front protective film, and manufacturing a back-cavity pattern;
S3.2: dry etching the front protective film and the silicon-based substrate to form the back-cavity structure, and cleaning to remove the photoresist;
S3.3: sputtering a bottom seed layer on the front of the silicon-based substrate;
S3.4: spin-coating a photoresist on the bottom seed layer;
S3.5: electroplating the bottom seed layer, and cleaning to remove the photoresist;
S3.6: etching off the bottom seed layer with an ion beam to form a complete bottom structure;
S3.7: filling a back cavity with benzocyclobutene (BCB) through multiple times of spin-coating, such that the back cavity is fully filled after curing; and
S3.8: mechanically smoothing a top BCB medium layer.

5. The method for processing a 3D silicon-based transfer structure based on a photosensitive composite according to claim 4, wherein in S3.2, the dry etching to form the back-cavity structure is conducted with a size of 79 μm; and
in S3.5, a thermally-conductive adhesive tape is used to bond a metal exposed on the back during the electroplating the front of the silicon-based substrate.

6. The method for processing a 3D silicon-based transfer structure based on a photosensitive composite according to claim 1, wherein S4 comprises:
S4.1: spin-coating a medium layer as a back-cavity mask layer on the BCB medium layer that has been mechanically smoothed on the front of the silicon-based substrate;
S4.2: thoroughly etching off the BCB outside the back-cavity mask layer through medium etching;
S4.3: spin-coating a surface medium layer on the back-cavity mask layer on the front of the silicon-based substrate, and manufacturing a pattern;
S4.4: sputtering a top metal layer on the surface medium layer on the front of the silicon-based substrate;
S4.5: spin-coating a photoresist on the top metal layer, and manufacturing a pattern;
S4.6: electroplating the top metal layer, and removing the residual photoresist; and
S4.7: using an ion beam to etch off a part of the top metal layer that is not electroplated.

7. The method for processing a 3D silicon-based transfer structure based on a photosensitive composite according to claim 6, wherein in S4.1, a size of the medium mask layer is expanded by 200 μm compared with a perimeter of the back-cavity structure; and
in S4.2, a top medium mask layer left after the medium etching has a height of 8 μm.

8. The method for processing a 3D silicon-based transfer structure based on a photosensitive composite according to claim 1, wherein S5 comprises:
S5.1: spin-coating a photoresist on the back of the silicon-based substrate, and developing to obtain a mask;
S5.2: conducting the bulk silicon etching through the dry etching, and removing the residual photoresist; and
S5.3: scribing the silicon-based substrate to complete manufacture of the transfer structure.

9. The method for processing a 3D silicon-based transfer structure based on a photosensitive composite according to claim 1, wherein the front protective film and the back protective film each are a Si₃N₄ film; and
the dry etching refers to inductively coupled plasma (ICP) dry etching.

10. A device manufactured by the method for processing a 3D silicon-based transfer structure based on a photosensitive composite according to any one of claims 1 to 9.
